(19) United States
(12) Patent Application Publication
(10) Pub. No.: US 2013/0287989 A1
(43) Pub. Date: Oct. 31, 2013

(54) GLASS MEMBER PROVIDED WITH SEALING MATERIAL LAYER ELECTRONIC DEVICE USING IT AND PROCESS FOR PRODUCING THE ELECTRONIC DEVICE

(71) Applicant: Asahi Glass Company, Limited, Chiyoda-ku (JP)

(72) Inventor: Sohei KAWANAMI, Chiyoda-ku (JP)

(21) Appl. No.: 13/928,795

(22) Filed: Jun. 27, 2013

Related U.S. Application Data
(63) Continuation of application No. PCT/JP2011/080092, filed on Dec. 26, 2011.

(30) Foreign Application Priority Data
Dec. 27, 2010 (JP) 2010-291040

(51) Int. Cl. C03C 27/06; H01L 23/10

(52) U.S. Cl. CPC C03C 27/06; H01L 23/10
USPC 428/76; 428/212

(57) ABSTRACT

A glass substrate 3 has a surface 3a provided with a sealing region. On the sealing region of the glass substrate 3, a sealing material layer 9 having a thickness of less than 7 μm is formed. The sealing material layer 9 is made of a fired layer of a glass material for sealing which contains a sealing glass and an inorganic filler containing a laser absorbent, wherein the content of the inorganic filler is from 2 to 44 vol %. The surface area of the inorganic filler in the glass material for sealing is within a range of more than 6 m²/cm³ and less than 14 m²/cm³. The difference between the thermal expansion coefficient α₁ of the sealing material layer 9 and the thermal expansion coefficient α₂ of the glass substrate 3 is within a range of from 15 to 70(×10⁻⁷/° C.).

### TECHNICAL FIELD

The present invention relates to a glass member provided with a sealing material layer, an electronic device using it and a process for producing the electronic device.

### BACKGROUND ART

A flat panel display device (FPD) such as an organic EL (Electro-Luminescence) display (OELD), a field emission display (FED), a plasma display panel (PDP) or a liquid crystal display device (LCD) has such a structure that a glass substrate for an element having a display element such as a light-emitting element formed and a glass substrate for sealing are disposed to face each other and the light-emitting element is sealed in a glass package comprising two such glass substrates that are sealed together (Patent Document 1). Also for a solar cell such as a dye-sensitized solar cell, application of a glass package having a solar cell element sealed with two glass substrates has been studied (Patent Document 2).

As a sealing material to seal a space between two glass substrates, application of sealing glass excellent in the moisture resistance, etc. is in progress. Since the sealing temperature of the sealing glass is at a level of from 400 to 600° C., properties of an electronic element portion of the organic EL (OEL) element or the dye-sensitized solar cell will be deteriorated when firing is conducted by using a conventional heating furnace. Accordingly, it has been attempted that a sealing material layer (a layer of a glass material for sealing) containing a laser absorbent is disposed between sealing regions provided on the peripheral portions of two glass substrates, and the layer is irradiated with a laser light to heat and melt the layer thereby to form a sealing layer (Patent Documents 1 and 2).

Sealing by laser irradiation (laser sealing) can suppress thermal influences over the electronic element portion, and on the contrary, it has a disadvantage that cracking, breakage, etc. are likely to form in the glass substrate or the sealing layer. One reason of the problem may be the difference in the thermal expansion coefficient between the glass substrate and the sealing glass. With respect to this point, Patent Document 2 describes a sealing material having a thermal expansion coefficient within 10×10⁻⁷/° C. from that of the glass substrate. Since the thermal expansion coefficient of a sealing glass is larger than that of a glass substrate in general, besides a laser absorbent, a low-expansion filler such as silica, alumina, zirconia or cordierite is added to the sealing glass to obtain a sealing material having a low expansion coefficient.

Whereas, reduction of the thickness of a glass package constituting e.g. a FPD or a solar cell tends to be in progress, and for this purpose, it is required to narrow the distance (the gap) between the glass substrates to be, for example, less than 7 μm. Since e.g. the low-expansion filler is added to the sealing material as described above, it becomes necessary to reduce the particle size of the filler particles along with narrowing of the substrate distance. Reduction of the particle size of the filler particles causes increase of the specific surface area, and a sharing stress between the sealing glass melted by heat of the laser light and the filler particles increases to reduce fluidity. Accordingly, it becomes necessary to increase the process temperature (heating temperature) by the laser light, but when the process temperature is increased, a problem such that a crack or breakage etc. tends to occur in the glass substrates or the sealing layer.

### PRIOR ART DOCUMENTS

### Patent Documents

Patent Document 1: JP-A-2006-524419
Patent Document 2: JP-A-2008-115057

### DISCLOSURE OF INVENTION

### Technical Problem

It is an object of the present invention to provide a glass member provided with a sealing material layer which is capable of preventing a trouble such as cracking or breakage of glass substrates or a sealing layer even in a case where the distance between two glass substrates is narrowed; an electronic device employing such a glass member provided with a sealing material layer and having high airtightness and reliability; and a process for producing such an electronic device.

### Solution to Problem

The glass member provided with a sealing material layer of the present invention comprises a glass substrate having a surface having a sealing region; and, formed on the sealing region of the glass substrate, a sealing material layer having a thickness of less than 7 μm and made of a material obtained by firing a glass material for sealing that contains a sealing glass and an inorganic filler containing a laser absorbent; wherein the glass material for sealing contains the inorganic filler in an amount within a range of from 2 to 44 vol % based on the total amount of the sealing glass and the inorganic filler, and the surface area of the inorganic filler in the glass material for sealing is within a range of more than 6 m²/cm³ and less than 14 m²/cm³; and wherein the difference between the thermal expansion coefficient α₁₁ of the material of the sealing material layer and the thermal expansion coefficient α₂ of the glass substrate is within a range of from 15 to 70(×10⁻⁷/° C.).

The electronic device of the present invention comprises a first glass substrate having a first surface having a first sealing region; a second glass substrate having a second surface having a second sealing region corresponding to the first sealing region and disposed so that the second surface is opposed to the first surface; an electronic element portion provided between the first glass substrate and the second glass substrate; and a sealing layer which is formed between the first sealing region of the first glass substrate and the second sealing region of the second glass substrate to seal the electronic element portion and which has a thickness of less than 7 μm and is made of a material obtained by melting and solidifying a glass material for sealing that contains a sealing glass and an inorganic filler containing a laser absorbent; wherein the glass material for sealing contains the inorganic filler in an amount within a range of from 2 to 44 vol % based on the total amount of the sealing glass and the inorganic filler, and the surface area of the inorganic filler in the glass material for sealing is within a range of more than 6 m²/cm³ and less than 14 m²/cm³; and wherein the difference between the thermal expansion coefficient α₁₂ of the material of the sealing layer and the thermal expansion coefficient α₂ of at least one of the first glass substrate and the second glass substrate is within the range of from 15 to 70(×10⁻⁷/° C.).

The process for producing an electronic device of the present invention comprises preparing a first glass substrate having a first surface having a first sealing region; preparing a second glass substrate having a second surface having a second sealing region corresponding to the first sealing region and provided with a sealing material layer having a thickness of less than 7 μm formed on the second sealing region and made of a material obtained by firing a glass material for sealing that contains a sealing glass and an inorganic filler containing a laser absorbent; laminating the first glass substrate and the second glass substrate with the sealing material layer interposed so that the first surface and the second surface are opposed to each other; and irradiating the sealing material layer with a laser light through the first glass substrate or the second glass substrate to melt and solidify the sealing material layer thereby to form a sealing layer to seal the electronic element portion provided between the first glass substrate and the second glass substrate; wherein the glass material for sealing contains the inorganic filler in an amount within a range of from 2 to 44 vol % based on the total amount of the sealing glass and the inorganic filler, and the surface area of the inorganic filler in the glass material for sealing is within a range of more than 6 m²/cm³ and less than 14 m²/cm³; and wherein the difference between the thermal expansion coefficient α₁₁ of the material of the sealing material layer and the thermal expansion coefficient α₂ of at least one of the first glass substrate and the second glass substrate is within a range of from 15 to 70(×10⁻⁷/° C.).

The above “preparing a first glass substrate” and “preparing a second glass substrate” may be carried out in the order as described above, or in a reversed order, or they may be simultaneously carried out in parallel. The subsequent “laminating the first glass substrate and the second glass substrate” and “irradiating the sealing material layer” are carried out in this order.

The above expression “to” showing a numerical range is used to include the numerical values before and after “to” as the lower limit value and the upper limit value, respectively, and the same applies hereinafter in this specification.

### Advantageous Effects of Invention

By the glass member provided with a sealing material layer, an electronic device employing it and a process for producing the electronic device of the present invention, it is possible to prevent a trouble such as cracking or breakage of glass substrates or a sealing layer at a time of laser sealing in a case where the distance between two glass substrates is narrowed. Accordingly, it is possible to increase the sealing property between the glass substrates and its reliability, and to provide an electronic device having high airtightness and reliability with good reproducibility.

### BRIEF DESCRIPTION OF DRAWINGS

FIG. 1 is a cross-sectional view illustrating the construction of an electronic device according to an embodiment of the present invention.

FIGS. 2(a) to 2(d) are cross-sectional views illustrating production states in the respective steps in the process for production of an electronic device according to the embodiment of the present invention.

FIG. 3 is a plan view illustrating a first glass substrate used in the process for production of an electronic device shown in FIGS. 2(a) to 2(d).

FIG. 4 is a cross-sectional view along the line A-A in FIG. 3.

FIG. 5 is a plan view illustrating a second glass substrate used in the process for production of an electronic device shown in FIGS. 2(a) to 2(d).

FIG. 6 is a cross-sectional view along the line A-A in FIG. 5.

FIG. 7 is a view showing an example of the relation between the strain amount of a glass substrate, that is laser-sealed by employing a sealing material layer having a thickness of less than 7 μm, and the laser processing temperature (heating temperature).

### DESCRIPTION OF EMBODIMENTS

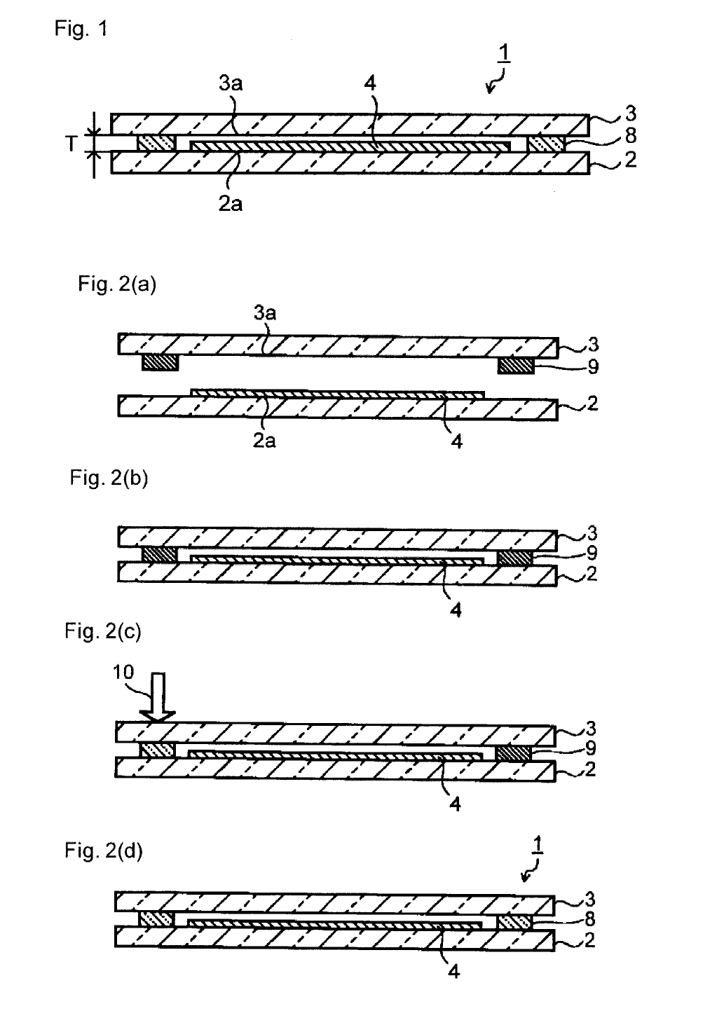

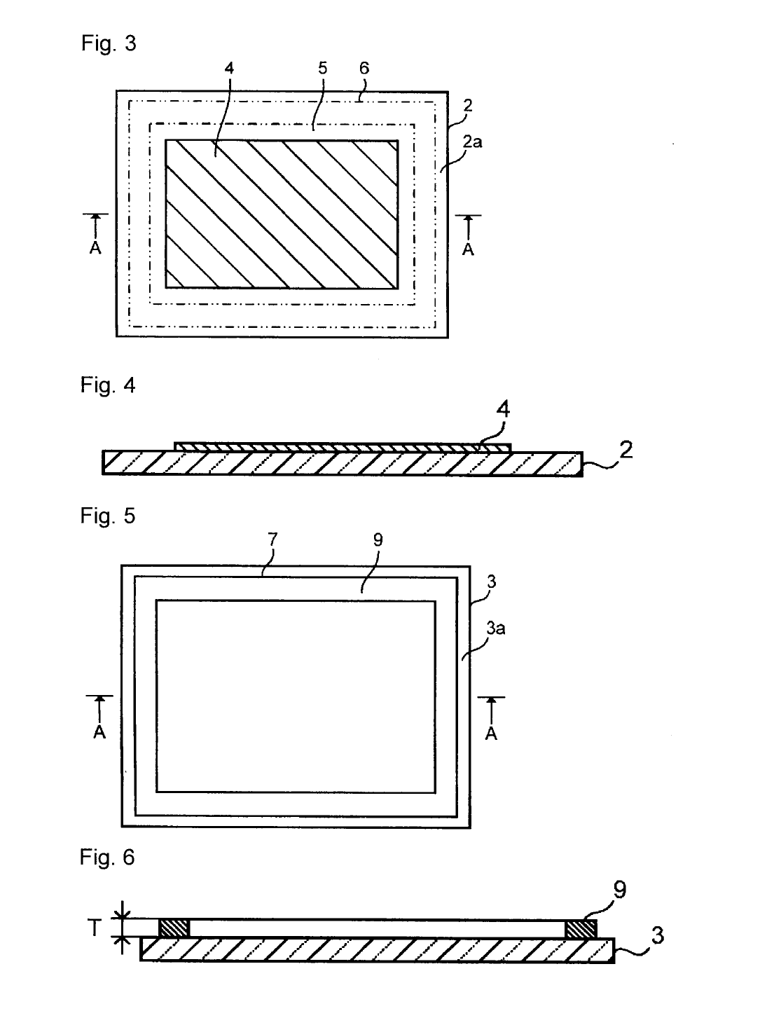

Now, the embodiments of the present invention will be described with reference to drawings. FIG. 1 is a view illustrating the construction of an electronic device according to an embodiment of the present invention, FIGS. 2(a) to 2(d) are views illustrating the process for production of an electronic device according to the embodiment of the present invention, and FIGS. 3 to 6 are views illustrating the structures of first and second glass substrates to be used in the process for production of an electronic device.

An electronic device 1 shown in FIG. 1 constitutes a FPD such as an OELD, a FED, a PDP or a LCD, an illumination device employing a light-emitting element such as an OEL element, or a solar cell such as a dye-sensitized solar cell, a thin film silicon solar cell or a compound semiconductor solar cell. An electronic device 1 comprises a first glass substrate 2 and a second glass substrate 3. The first and second glass substrates 2 and 3 are constituted, for example, by alkali-free glass or soda lime glass having a various known composition. Alkali-free glass has a thermal expansion coefficient of about from 35 to 40(×10⁻⁷/° C.). Soda lime glass has a thermal expansion coefficient of about from 80 to 90(×10⁻⁷/° C.). A typical glass composition for alkali free glass may be one comprising, as represented by mass %, from 50 to 70% of SiO₂, from 1 to 20% of Al₂O₃, from 0 to 15% of B₂O₃, from 0 to 30% of MgO, from 0 to 30% of CaO, from 0 to 30% of SrO and from 0 to 30% of BaO, and a typical glass composition for soda lime glass comprises, as represented by mass %, from 55 to 75% of SiO₂, from 0.5 to 10% of Al₂O₃, from 2 to 10% of CaO, from 0 to 10% of SrO, from 1 to 10% of Na₂O and from 0 to 10% of K₂O. However, they are not limited to such examples.

Between a surface 2a of the first glass substrate 2 and a surface 3a of the second glass substrate 3 opposed thereto, an electronic element portion 4 according to the electronic device 1, is provided. The electronic element portion 4, for example, has an OEL element in a case of OELD or OEL illumination, a plasma emission element in a case of PDP, a liquid crystal display element in a case of LCD, and a solar cell element in a case of solar cell. The electronic element portion 4 having a light-emitting element such as a liquid crystal display element, a plasma-emitting element or an OEL element, or a solar cell element etc., has any one of various known structures. The electronic device 1 of this embodiment is not limited to the element structure of the electronic element portion 4.

In the electronic device 1 shown in FIG. 1, the first glass substrate 2 constitutes a glass substrate for an element, and an element structure of e.g. an OEL element or a PDP element is formed as an electronic element portion 4 on a surface of the substrate. The second glass substrate 3 constitutes a glass substrate for sealing the electronic element portion 4 formed on the surface of the first glass substrate 2. However, the construction of the electronic device 1 is not limited thereto. For example, when the electronic element portion 4 is e.g. a liquid crystal display element or a solar cell element, element films such as wire films or electrode films forming element structures are formed on surfaces 2a and 3a of the first and second glass substrates 2 and 3. The element films constituting the electronic element portion and the element structure based on such films are formed on at least one of the surfaces 2a and 3a of the first and second substrates 2 and 3.

On the surface 2a of the first glass substrate 2 to be employed for production of the electronic device 1, as shown in FIGS. 3 and 4, a first sealing region 6 is provided along the entire or substantially entire outer periphery of an element region 5 in which the electronic element portion is formed. The first sealing region 6 is provided so as to surround the element region 5. On the surface 3a of the second glass substrate 3, as shown in FIGS. 5 and 6, a second sealing region 7 corresponding to the first sealing region 6 is provided. The first and second sealing regions 6 and 7 become regions for forming the sealing layer (the second sealing region 7 becomes a region for forming a sealing material layer). Here, also on the surface 3a of the second glass substrate 3, an element region may be provided as the case requires.

The first glass substrate 2 and the second glass substrate 3 are disposed with a predetermined gap so that the surface 2a having the element region 5 and the first sealing region 6 is opposed to the surface 3a having the second sealing region 7. The gap between the first glass substrate 2 and the second glass substrate 3 is sealed by a sealing layer 8. Namely, the sealing layer 8 is formed between the sealing region 6 of the first glass substrate 2 and the sealing region 7 of the second glass substrate 3 over the entire periphery of the first glass substrate 2 and the second glass substrate 3 so as to seal the electronic element portion 4. The electronic element portion 4 is hermetically sealed by a glass panel constituted by the first glass substrate 2, the second glass substrate 3 and the sealing layer 8. The sealing layer 8 has a thickness T of less than 7 μm.

In a case of applying e.g. an OEL element as the electronic element portion 4, partially, a space remains between the first glass substrate 2 and the second glass substrate 3. Such a space may remain as it is or the space may be filled with e.g. a transparent resin. The transparent resin may be bonded to the glass substrates 2 and 3 or it may be simply in contact with the glass substrates 2 and 3. Further, in a case of applying e.g. a liquid crystal display element or a dye-sensitized solar cell element as the electronic element portion 4, the electronic element portion 4 may be disposed in the entire gap between the first glass substrate 2 and the second glass substrate 3.

The sealing layer 8 is made of a melt-bonded layer formed by melting the sealing material layer 9 formed on the sealing region 7 of the second glass substrate 3 by laser light to bond it to the sealing region 6 of the first glass substrate 2. Namely, in the sealing region 7 of the second glass substrate 3 to be employed for production of the electronic device 1, a frame-shaped (i.e. frame-form) sealing material layer 9 is formed along the entire or substantially entire periphery of the second glass substrate 3 as shown in FIGS. 5 and 6. The sealing material layer 9 formed in the sealing region 7 of the second glass substrate 3 is melt-bonded to the sealing region 6 of the first glass substrate 2 by heat of laser light, to thereby form a sealing layer 8 sealing a space (element-disposing space) between the first glass substrate 2 and the second glass substrate 3.

The sealing material layer 9 is a layer formed by firing a layer of the glass material for sealing and is made of a material having the glass material for sealing fired. The glass material for sealing contains a sealing glass and a laser absorbent and may further contain a low-expansion filler as the case requires. Hereinafter, the essential laser absorbent and optional low-expansion filler are generally referred to as an inorganic filler. That is, the inorganic filler contains at least a laser absorbent and may further contain a low-expansion filler as the case requires. Further, the glass material for sealing may further contain other additives, as the case requires. The glass material for sealing contains a sealing glass and an inorganic filler and may further contain other additives, as the case requires. Such other additives may be inorganic fillers other than the laser absorbent and the low-expansion filler. However, as mentioned hereinafter, such other additives exclude components which disappear at the time of firing. In the present invention, the above-mentioned sealing glass, laser absorbent and low-expansion filler may, respectively, be in a powder form or in a particle form, and the sealing glass powder may simply be referred to as a sealing glass, and the laser absorbent particles or laser absorbent powder may simply be referred to as a laser absorbent. Further, the low-expansion filler particles or low-expansion filler powder may simply be referred to as a low-expansion filler.

For the sealing glass (i.e. glass frit), for example, low melting point glass such as tin-phosphate glass, bismuth glass, vanadium glass or lead glass may be used. Among them, considering the sealing property (adhesion property) to the glass substrates 2 and 3 and reliability (bonding reliability and hermetical sealing property) and in addition, the influences over the environment and the human body, it is preferred to use sealing glass comprising bismuth glass or tin-phosphate glass.

The bismuth glass (glass frit) preferably has a composition comprising, as represented by mass %, from 70 to 90 mass % of Bi₂O₃, from 1 to 20 mass % of ZnO and from 2 to 12 mass % of B₂O₃ (basically, the total content will be 100 mass %). Bi₂O₃ is a component to form a glass network. If the content of Bi₂O₃ is less than 70 mass %, the softening point of the low melting glass will be high, whereby sealing at low temperature will be difficult. If the content of Bi₂O₃ exceeds 90 mass %, the glass will hardly be vitrified and in addition, the thermal expansion coefficient tends to be too high.

ZnO is a component to lower the thermal expansion coefficient or the like. If the content of ZnO is less than 1 mass %, the glass will hardly be vitrified. If the content of ZnO exceeds 20 mass %, the stability at the time of formation of the low melting glass will be decreased, and devitrification is likely to occur. B₂O₃ is a component to form a glass skeleton and to broaden a range within which the glass can be vitrified. If the content of B₂O₃ is less than 2 mass %, the glass will hardly be vitrified, and if it exceeds 12 mass %, the softening point will be too high, whereby sealing at low temperature will be difficult even if a load is applied at the time of the sealing.

The glass formed by the above three components has a low glass transition point and is suitable as a sealing material at low temperature, and it may contain an optional component such as Al₂O₃, CeO₂, SiO₂, Ag₂O, MoO₃, Nb₂O₃, Ta₂O₅, Ga₂O₃, Sb₂O₃, Li₂O, Na₂O, K₂O, Cs₂O, CaO, SrO, BaO, WO₃, P₂O₅ or SnOₓ (wherein x is 1 or 2). However, if the content of the optional components is too high, the glass will be unstable, whereby devitrification may occur, or the glass transition point or the softening point may be increased. Thus, the total content of the optional components is preferably at most 30 mass %. In this case, the glass composition is adjusted so that the total amount of the basic components and the optional components basically becomes 100 mass %.

The tin-phosphate glass (glass frit) preferably has a composition comprising, as represented by mol %, from 20 to 68 mol % of SnO, from 0.5 to 5 mol % of SnO₂ and from 20 to 40 mol % of P₂O₅ (basically, the total amount will be 100 mol %). SnO is a component to make the glass have a low melting point. If the content of SnO is less than 20 mol %, the viscosity of glass will be high and the sealing temperature will be too high, and if the content exceeds 68 mass %, the glass will not be vitrified.

SnO₂ is a component to stabilize glass. If the content of SnO₂ is less than 0.5 mol %, SnO₂ will be separated and precipitate in the glass softened and melted at the time of the sealing operation, and the fluidity will be impaired and the sealing operation property will be decreased. If the content of SnO₂ exceeds 5 mol %, SnO₂ is likely to precipitate in the melt of the low melting glass. P₂O₅ is a component to form a glass skeleton. If the content of P₂O₅ is less than 20 mol %, the glass will not be vitrified, and if the content exceeds 40 mol %, deterioration of the weather resistance which is a drawback specific to phosphate glass may occur.

Here, the ratios (mol %) of SnO and SnO₂ in the glass frit can be determined as follows. First, the glass frit (low-melting glass powder) is subjected to acid decomposition, and then the total amount of Sn atoms contained in the glass frit is measured by ICP emission spectroscopy. Then, the amount of Sn²⁺ (SnO) can be obtained by the iodometric titration after the acid decomposition, and thus the amount of Sn⁴⁺ (SnO₂) is determined by subtracting the above obtained amount of Sn²⁺ from the total amount of the Sn atoms.

The glass formed by the above three components has a low glass transition point and is suitable as a sealing material at low temperature, and it may contain e.g. a component to form a glass skeleton such as SiO₂, a component to stabilize the glass such as ZnO, B₂O₃, Al₂O₃, WO₃, MoO₃, Nb₂O₅, TiO₂, ZrO₂, Li₂O, Na₂O, K₂O, Cs₂O, MgO, CaO, SrO or BaO as an optional component. However, if the content of the optional component is too high, the glass will be unstable, whereby devitrification may occur, or the glass transition point or the softening point may be increased. Thus, the total content of the optional components is preferably at most 30 mol %. In this case, the glass composition is adjusted so that the total amount of the basic components and the optional components basically becomes 100 mol %.

The glass material for sealing contains an inorganic filler containing a laser absorbent and a low-expansion filler. However, since it is possible to obtain the function as an inorganic filler by the laser absorber alone, the low-expansion filler is an optional component and the low-expansion filler may not necessarily be contained. The laser absorbent is an essential component for heating and melting with laser light the sealing material layer 9 formed by firing the glass material for sealing. Thus, the glass material for sealing contains besides the sealing glass, a laser absorbent as an essential component and may further contain a low-expansion filler as an optional component.

As the laser absorbent, at least one metal selected from the group consisting of Fe, Cr, Mn, Co, Ni and Cu, or at least one member selected from metal compounds such as oxides containing such metals, may be employed. Further, the laser absorbent may be a pigment other than those, for example, an oxide of vanadium (specifically VO, VO₂ or V₂O₅).

As the low-expansion filler, at least one member selected from silica, alumina, zirconia, zirconium silicate, aluminum titanate, mullite, cordierite, eucryptite, spondumene, a zirconium phosphate compound, quartz solid solution, soda lime glass and borosilicate glass, is preferably employed. As the zirconium phosphate compound, (ZrO)₂P₂O₇, NaZr₂(PO₄)₃, KZr₂(PO₄)₃, Ca_{0.5}Zr₂(PO₄)₃, NbZr(PO₄)₃, Zr₂(WO₃)(PO₄)₂ or a complex compound of them may, for example, be mentioned. The low-expansion filler is one having a thermal expansion coefficient lower than that of the sealing glass.

The glass material for sealing may contain another inorganic filler (for example, an inorganic filler having a thermal expansion coefficient equivalent or higher than the thermal expansion coefficient of the sealing glass) besides the laser absorbent and the low-expansion filler. However, usually, it is not necessary to incorporate such another filler. Hereinafter, the inorganic filler means the laser absorbent as an essential component and the low-expansion filler as an optional component, and e.g. the quantitative ratio of the inorganic filler means the ratio of total amount of the laser absorbent and the low-expansion filler, unless otherwise specified.

The thickness T of the sealing material layer 9 is less than 7 μm or further preferably at most 6 μm in order to narrow the substrate distance (the distance between the first glass substrate 2 and the second glass substrate 3) after sealing. Although the thickness T of the sealing material layer 9 depends also on the structure of the electronic device 1, it is practically preferably at least 1 μm. In order to form a sealing material layer 9 having such a thickness, it is required to miniaturize the particle size of the laser absorbent or the low-expansion filler as the inorganic filler. Specifically, it is necessary to make the maximum particle size of the inorganic filler particles to be less than the thickness T of the sealing material layer 9. In conventional fillers, along with miniaturization of the maximum particle size, all inorganic filler particles tend to be miniaturized. Further, conventional glass materials for sealing contain a relatively large amount of a low-expansion filler in order to reduce the difference in the thermal expansion coefficient from the glass substrates 2 and 3.

In such a glass material for sealing containing a relatively large amount of a low-expansion filler in a fine particle state, since miniaturization of the particle size of the low-expansion filler increases the surface area as described above, the fluidity of the glass material for sealing decreases accordingly. In order to melt the glass material for sealing having a low fluidity by laser light, it is, for example, necessary to increase the power of laser light to raise the processing temperature (heating temperature). However, when the processing temperature by laser light is raised, cracking or breakage tends to occur in the glass substrates 2 and 3 or the sealing layer 8.

Thus, in the above embodiment of the present invention, the amount of a low-expansion filler to be incorporated to the glass material for sealing is reduced. Specifically, the total content of the low-expansion filler and the laser absorbent in the glass material for sealing is set to be within the range of from 2 to 44 vol %. When the content of the low-expansion filler in the glass material for sealing is reduced, the difference between the thermal expansion coefficient α₁₁ of the glass material for sealing and the thermal expansion coefficient α₂ of the glass substrates 2 and 3 increases. Since the thermal expansion difference between the sealing material layer 9 comprising a fired glass material for sealing and the glass substrates 2 and 3 is considered to be the main cause of cracking or breakage of the glass substrates 2 and 3 or the sealing layer 8, the conventional glass materials for sealing contain a relatively large amount of a low-expansion filler as described above.

Hereinafter the fired glass material for sealing being a material constituting the sealing material layer 9 may also be referred to simply as the sealing material. The thermal expansion coefficient α₁₁ of the sealing material may also be referred to as the thermal expansion coefficient α₁₁ of the sealing material layer.

The sealing layer 8 is a layer made of a melt-bonded material of the material constituting the sealing material layer 9 (i.e. fired glass material for sealing), and it is usually a layer formed by melting and then cooling to solidify the sealing material layer 9. Even if the constituting material of the sealing material layer 9 is once melted and then cooled for sealing, the constituting material of the sealing layer 8 and the constituting material of the sealing material layer 9 are considered to be substantially not changed as material. Accordingly, the thermal expansion coefficient α₁₂ of the constituting material of the sealing layer 8 (i.e. the material obtained by melting and solidifying the sealing material) is equal to the thermal expansion coefficient α₁₁ of the above-described sealing material.

Cracking or breakage of the glass substrates 2 and 3 or the sealing layer 8 in a laser sealing step is caused mainly by a residual stress formed in the glass substrates 2 and 3 by melting and solidification of the sealing material layer 9. When the thermal expansion coefficient α₁₁ of the sealing material is larger than the thermal expansion coefficient α₂ of the glass substrates 2 and 3, the shrinkage of the sealing material layer 9 is larger than the shrinkage of the glass substrates 2 and 3 in the laser sealing step (heating and cooling step), and a strong compressive stress (residual stress) is formed in the glass substrates 2 and 3. The residual stress σ formed in the glass substrates 2 and 3 is represented by the following formula.

σ=α·ΔT·E/(1−v) (1)

In the above formula (I), α is the difference between the thermal expansion coefficient α₁₁ of the constituting material (sealing material) of the sealing material layer 9 and the thermal expansion coefficient α₂ of the glass substrates 2 ad 3, ΔT is the temperature difference at a time of laser sealing (i.e. the temperature difference from the melting temperature (processing temperature) of the sealing material layer 9 to a cooled room temperature) divided by cooling time, E is Young's modulus of the sealing material or the glass substrates 2 and 3, and v is a Poisson's ratio. In a case of laser sealing, since the cooing time becomes substantially constant when the scanning speed and the spot size of laser light are constant, ΔT substantially becomes the temperature difference at the time of laser sealing.

In conventional glass materials for sealing, a method of reducing the residual stress by reducing α in formula (I) of the material at the time of laser sealing or after laser sealing, has been mainly employed. With respect to such a point, it has become clear that when the thickness T of the sealing material layer 9 is reduced to be less than 7 μm and further to be at most 6 μm, influence of the value of ΔT increases. Namely, when the laser processing temperature (heating temperature) is increased to increase the fluidity of the sealing material, increase of the residual stress σ becomes significant.

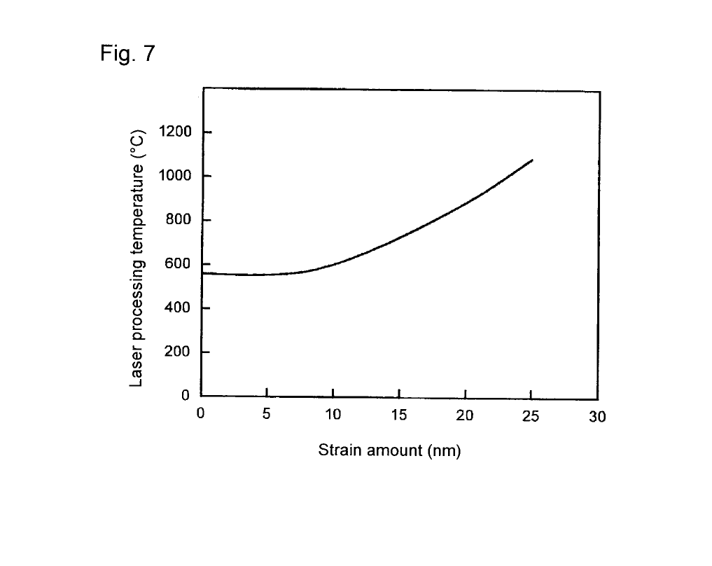

FIG. 7 shows an example of the relation between the strain amount of glass substrates and the laser processing temperature (i.e. heating temperature) at the time of laser-sealing the glass substrates (thickness: 0.7 mm, thermal expansion coefficient α₂: 38×10⁻⁷/° C.) by means of a thin sealing material layer 9 (thickness: 4 μm, thermal expansion coefficient α₁₁: 82×10⁻⁷/° C.). As evident from FIG. 7, the strain amount of the glass substrates increases along with a rise of the laser processing temperature, which indicates that the residual stress in the glass substrates is increased by the laser sealing step (heating and cooling step). On the other hand, when the thickness T of the sealing material layer 9 is made to be as thin as less than 7 μm, since the influence of the shrinkage amount of the sealing material layer 9 is reduced, the stress due to the difference in the shrinkage amount (thermal expansion difference) between the glass substrates 2 and 3 and the sealing material layer 9 becomes small as compared with a case where the film thickness T of the sealing material layer 9 is thick.

Thus, when a thin sealing material layer 9 having a thickness T of less than 7 μm is employed, it is more important to suppress a rise of the laser processing temperature than reduction of the thermal expansion difference between the sealing material layer 9 and the glass substrates 2 and 3. Thus, in this embodiment, in order to lower the laser processing temperature, the total content (content of the inorganic filler) of the low-expansion filler and the laser absorbent in the glass material for sealing is set to be within the range of from 2 to 44 vol %. Fluidity of the sealing material is influenced not only by the low-expansion filler but also by the laser absorbent. For this reason, the total content of the low-expansion filler and the laser absorbent in the glass material for sealing is set to be at most 44 vol %. When the total content of the low-expansion filler and the laser absorbent is at most 44 vol %, it is possible to obtain the effect of lowering the laser processing temperature (heating temperature).

When the total content of the low-expansion filler and the laser absorbent is reduced, the thermal expansion difference between the sealing material layer 9 and the glass substrates 2 and 3 is increased particularly by the influence of reduction of the content of the low-expansion filler, but since the lowering of fluidity of the sealing material is suppressed, it is possible to lower the laser processing temperature (heating temperature). That is, the sealing material can be well fluidized at a relatively low laser processing temperature, and accordingly, residual stress in the glass substrates 2 and 3 during the laser sealing is reduced. Accordingly, it is possible to suppress cracking or breakage of the glass substrates 2 and 3 or the sealing layer 8.

The laser absorbent is an essential component for carrying out a laser sealing step, and the content is preferably within the range of from 2 to 40 vol % based on the glass material for sealing. When the content of the laser absorbent is less than 2 vol %, it may not be possible to sufficiently melt the sealing material layer 9 at a time of laser irradiation. This may cause poor bonding. On the other hand, if the content of laser absorbent exceeds 40 vol %, local heat generation in the vicinity of an interface with the second glass substrate 3 may occur at the time of laser irradiation to cause cracking in the second glass substrate 2, or fluidity of the molten glass material for sealing may be deteriorated to deteriorate the bonding property with the first glass substrate 2. In a case where the thickness T of the sealing material layer 9 is as thin as less than 7 μm, the function of the inorganic filler can be obtained even by the laser absorbent only, and accordingly, the laser absorbent may be incorporated up to 40 vol % based on the glass material for sealing.

The low-expansion filler is preferably contained to reduce the thermal expansion difference between the sealing material layer 9 and the glass substrates 2 and 3, but when the low-expansion filler has a particle size applicable to a thin sealing material layer 9 having a thickness T of less than 7 μm, the content is preferably reduced since the low-expansion filler may become a factor of lowering the fluidity at a time of laser processing. For this reason, the content of the low-expansion filler is preferably at most 40 vol % based on the glass material for sealing. If the content of the low-expansion filler exceeds 40 vol %, a rise of the laser processing temperature is unavoidable. The content of the low-expansion filler is practically within the range of at least 0.1 vol %, preferably at least 1 vol %, but as described later, the glass material for sealing may not necessarily contain the low-expansion filler in some cases.

Since the sealing material of this embodiment has a reduced content of the low-expansion filler, the difference between the thermal expansion coefficient α₁₁ of the sealing material layer 9 or the thermal expansion coefficient α₁₂ of the sealing layer 8 and the thermal expansion coefficient α₂ of the glass substrates 2 and 3 is large. Specifically, the thermal expansion difference between the sealing material layer 9 or the sealing layer 8 and the glass substrates 2 and 3 is within the range of from 15 to 70(×10⁻⁷/° C.). In other words, when the thermal expansion difference is within the range of from 15 to 70(×10⁻⁷/° C.), it is possible to reduce the content of the low-expansion filler to be low or zero to maintain the fluidity of sealing material, and to lower the laser processing temperature (heating temperature) based on the fluidity, thereby to suppress cracking or breakage of the glass substrates 2 and 3 or the sealing layer 8.

Here, the thermal expansion coefficient α₁₁ of the sealing material layer 9, the thermal expansion coefficient α₁₂ of the sealing layer 8 and the thermal expansion coefficient α₂ of the glass substrates 2 and 3 are values measured by using a push-rod type thermal expansion coefficient measurement apparatus, and the temperature range for measuring the thermal expansion coefficients α₁₁, α₁₂ and α₂ is from 50 to 250° C. Further, the thermal expansion difference between the sealing material layer 9 and the glass substrates 2 and 3 is a value ((α₁₁−α₂) or (α₂−αᵢᵢ)) obtained by subtracting the smaller value from the larger value of the coefficients, and the large-small relation between the thermal expansion coefficient α₁₁ of the sealing material layer 9 and the thermal expansion coefficient α₂ of the glass substrates 2 and 3 may be any relation. The same applies to the thermal expansion difference between the sealing layer 8 and the glass substrates 2 and 3. Further, as mentioned above, the thermal expansion coefficient α₁₂ of the sealing layer 8 is equal to the thermal expansion coefficient α₁₁ of the sealing material layer 9, whereby the thermal expansion coefficient α₁₁ of the sealing material layer 9 may be regarded as the thermal expansion coefficient α₁₂ of the sealing layer 8.

When the thermal expansion difference between the sealing material and the glass substrates 2 and 3 is less than 15×10⁻⁷/° C., the sealing material contains a relatively large amount of the low-expansion filler, and a rise of the above-mentioned laser processing temperature is unavoidable. If the thermal expansion difference between the sealing material layer 9 and the glass substrates 2 and 3 exceeds 70×10⁻⁷/° C., by the influence of the laser processing temperature, an influence of the difference in the shrinkage amount between the glass substrates 2 and 3 and the sealing material layer 9 becomes large, whereby the cracking or breakage of the glass substrates 2 and 3 or the sealing layer 8 tends to occur even if the laser processing temperature is lowered.

Thus, when the thermal expansion difference between the sealing material layer 9 and the glass substrates 2 and 3 is within the range of at most 70×10⁻⁷/° C., it is possible to reduce the content of the low-expansion filler in the sealing material. Further, even in a case where the sealing material contains no low-expansion filler, when the thermal expansion difference between the sealing material layer 9 and the glass substrates 2 and 3 is at most 70×10⁻⁷/° C., it is possible to suppress cracking or breakage, etc. of the glass substrates 2 and 3 or the sealing layer 8. It is sufficient that the sealing material contains a laser absorbent as an inorganic filler, and the content of the low-expansion filler may be zero. For this reason, it is sufficient that the total content (content of the inorganic filler) of the low-expansion filler and the laser absorbent in the glass material for sealing is at least 2 vol % being the lower limit of the content of the laser absorbent.

Here, in order to reduce the difference in the shrinkage amount between the glass substrates 2 and 3 and the sealing material layer 9 at the time of laser sealing, the thermal expansion difference between the sealing material and the glass substrates 2 and 3 is preferably at most 60×10⁻⁷/° C., more preferably at most 55×10⁻⁷/° C. From these points of view, the glass material for sealing preferably contains the low-expansion filler within the range of at least 1 vol %. When the sealing material layer 9 is one produced by firing a glass material for sealing containing the laser absorbent within the range of from 2 to 40 vol % and the low-expansion filler within the range of from 1 to 40 vol %, it is possible to lower the laser processing temperature while reducing the difference in the shrinkage amount between the glass substrates 2 and 3 and the sealing material layer 9 at the time of laser sealing, which contributes to improvement of the sealing property and its reliability.

The fluidity of the sealing material and the laser processing temperature to be set according to the fluidity, are influenced not only by the content of the inorganic filler (laser absorbent and/or low-expansion filler) in the sealing material but also by the particle shape of the inorganic filler. As described above, the maximum particle size of the inorganic filler particles needs to be less than the thickness T of the sealing material layer 9. Further, it is preferred to reduce the specific surface area of the inorganic filler particles. Specifically, the surface area of the inorganic filler in the glass material for sealing is preferably within the range of more than 6 m²/cm³ and less than 14 m²/cm³. In the present invention, the surface area of the inorganic filler particles in the glass material for sealing is meant for the surface area of the laser absorbent particles only or of the laser absorbent particles and the low expansion filler particles. Here, in a case where the inorganic filler particles are composed of laser absorbent particles and low expansion filler particles, the surface area of the inorganic filler particles is the sum of the surface area of the laser absorbent particles and the surface area of the low expansion filler particles.

Here, the surface area of the inorganic filler in the glass material for sealing is a value represented by [(specific surface area of inorganic filler)×(specific gravity of inorganic filler)×(content of inorganic filler (vol %))]. For example, in a glass material for sealing containing a laser absorbent and a low-expansion filler, the surface area of the inorganic filler in the glass material for sealing (the total surface area of the laser absorbent and the low expansion filler) is obtained by [{(specific surface area of laser absorbent)×(specific gravity of laser absorbent)×(content of laser absorbent (vol %))+(specific surface area of low-expansion filler)}×{(specific gravity of low-expansion filler)×(content of low-expansion filler (vol %))}].

By making the surface area of the filler in the glass material for sealing to be within the range of more than 6 m²/cm³ and less than 14 m²/cm³, it is possible to further improve the fluidity of the sealing material and to further lower the laser processing temperature. In a case where the thickness T of the sealing material layer 9 is as thin as less than 7 μm, it is possible to increase the fluidity of the sealing material if the surface area of the inorganic filler in the glass material for sealing is more than 6 m²/cm³. On the other hand, if the surface area of the inorganic filler is not more than 6 m²/cm³, localization of the inorganic filler particles is likely to result in the sealing material layer 9 having a thickness T of less than 7 μm, and a local thermal expansion difference tends to be large. This causes stress concentration, whereby cracking, breakage, etc. of the glass substrates 2 and 3 or the sealing layer 8 tends to result.

The surface area of the inorganic filler in the glass material for sealing is more preferably within a range of more than 6 m²/cm³ and at most 13.5 m²/cm³. Such a surface area of the inorganic filler can be satisfied by controlling the particle size distribution of the laser absorbent particles or the low-expansion filler particles. Specifically, such a surface area can be obtained by adjusting the particle size distribution by classifying the respective powders by means of a sieve or wind separation at the time of preparing the laser absorbent or the low-expansion filler.

The electronic device 1 of the above embodiment is prepared, for example, by the following process. First, as shown in FIGS. 2(a), 5 and 6, a sealing material layer 9 is formed on a sealing region 7 of a second glass substrate 3. In forming the sealing material layer 9, first, a glass material for sealing is prepared so that the total content (content of the inorganic filler) of a low-expansion filler and a laser absorbent is within the range of from 2 to 44 vol %, so as to form a sealing material layer having a thermal expansion difference from the glass substrates 2 and 3 within the range of from 15 to 70×10⁻⁷/° C.).

The glass material for sealing comprises a composition containing a sealing glass, a laser absorbent and optionally a low-expansion filler and further containing additives other than those as the case requires. In this embodiment, additives such as a solvent and a binder disappearing from the composition by evaporation or burning at a time of firing are not included in the constituent components of the glass material for sealing. The components disappearing from the composition by evaporation or burning at the time of firing are additives usually essential for forming a layer of the glass material for sealing on a surface of glass substrate by e.g. coating. However, since these disappearing components are not components constituting the sealing material, they are not included in the constituent components of the glass material for sealing, and the composition ratio of the constituent components is defined as a constituent ratio excluding these disappearing components. A composition for forming a layer to be a sealing material layer 9 after firing, which contains the constituent components of the glass material for sealing and disappearing components such as a solvent and a binder, is hereinafter referred to as a sealing material paste. The composition ratio of the components disappearing by firing is determined considering properties such as a coating property required for the sealing material paste as well as the composition ratio of the components remaining after the firing. The sealing material paste is prepared by mixing the constituent components of the glass material for sealing and a vehicle.

The vehicle is a material produced by dissolving a resin being a binder component in a solvent. The resin for the vehicle may, for example, be an organic resin such as a cellulose resin such as methyl cellulose, ethyl cellulose, carboxymethyl cellulose, oxyethyl cellulose, benzyl cellulose, propyl cellulose or nitro cellulose; or an acrylic resin obtained by polymerizing at least one type of acrylic monomer such as methyl methacrylate, ethyl methacrylate, butyl methacrylate, 2-hydroxyethyl methacrylate, butyl acrylate or 2-hydroxyethyl acrylate. In the case of a cellulose resin, the solvent may be terpineol, butylcarbitol acetate, ethylcarbitol acetate, etc., and in the case of an acrylic resin, the solvent may be methylethyl ketone, terpineol, butylcarbitol acetate, ethylcarbitol acetate, etc.

The viscosity of the sealing material paste may be adjusted to the viscosity suitable for an apparatus for coating the glass substrate 3, and the viscosity may be adjusted by the ratio between the resin (binder component) and the solvent or the ratio between the component of the glass material for sealing and the vehicle. To the sealing material paste, additives such as a defoaming agent, a dispersing agent, etc. that are known as additives to a glass paste, may be added. These additives are also components usually disappearing at a time of firing. For preparation of the sealing material paste, a known method using a rotation type mixer provided with stirring blade, a roll mill or a ball mill, etc. may be used.

The above sealing material paste is applied on the sealing region 7 of the second glass substrate 3 and dried to form a coating layer of the sealing material paste. The sealing material paste is applied so that the film thickness after firing becomes less than 7 μm. The sealing material paste is applied on the second sealing region 7 by using, for example, a printing method such as screen printing or gravure printing, or applied on the second sealing region 7 by using e.g. a disperser. The coating layer of the sealing material paste is preferably dried at a temperature of at least 120° C. for at least 10 minutes. The drying step is carried out to remove the solvent in the coating layer. If the solvent remains in the coating layer, components such as a binder, etc. that are to be disappeared in the subsequent firing step, may not be sufficiently removed.

Next, the above coating layer of the sealing material paste is fired to form a sealing material layer 9. In the firing step, first, the coating layer is heated to a temperature of at most the glass transition point of the sealing glass (i.e. glass frit), to remove e.g. the binder component in the coating layer, and thereafter, it is heated to a temperature of at least the softening temperature of the sealing glass (glass frit) to melt the glass material for sealing to bond it to the glass substrate 3. Thus, a sealing material layer 9 comprising a fired material of the glass material for sealing (sealing material) is formed on the sealing region 7 of the second glass substrate 3.

Next, a first glass substrate 2 is prepared separately from the second glass substrate 3, and using these glass substrates 2 and 3, an electronic device 1 such as a FPD such as an OELD, a PDP or an LCD, an illumination device employing an OEL element or a solar cell such as a dye-sensitized solar cell, is prepared. Namely, as shown in FIG. 2(b), the first glass substrate 2 and the second glass substrate 3 are laminated via the sealing material layer 9 so that the surfaces 2a and 3a of the substrates are opposed to each other. Between the first glass substrate 2 and the second glass substrate 3, a gap based on the thickness of the sealing material layer 9, is formed.

Next, as shown in FIG. 2(c), the sealing material layer 9 is irradiated with laser light 10 through the second glass substrate 3. Here, the sealing material layer 9 may be irradiated with the laser light 10 through the first glass substrate 2. The sealing material layer 9 is irradiated with the laser light 10 while the laser light 10 is scanned along the frame shaped (i.e. frame-form) sealing material layer 9 formed over the entire periphery of the second glass substrate. Then, by irradiating the entire circumference of the sealing material layer 9 with the laser light 10 to melt the sealing material layer 9, a sealing layer 8 sealing a gap between the first glass substrate 2 and the second glass substrate 3 is formed as shown in FIG. 2(d). The thickness of the sealing layer 8 becomes slightly less than the thickness of the sealing material layer 9 but since the thickness of the sealing material layer 9 is as thin as less than 7 μm, the reduction of the thickness by laser sealing is extremely small. Accordingly, the thickness of the sealing layer 8 becomes approximately the same as the thickness of the sealing material layer 9. As mentioned above, the thickness of the sealing material layer 9 is set to be less than 7 μm, and accordingly, the obtainable sealing layer 8 becomes to be less than 7 μm.

Thus, an electronic device 1 is prepared, which comprises a glass package constituted by the first glass substrate 2, the second glass substrate 3 and the sealing layer 8, and an electronic element portion 4 provided between the first glass substrate 2 and the second glass substrate 3 and hermetically sealed by the glass package. Here, the glass package of this embodiment is not limited to be used as a component of the electronic device 1, but it can be applied to a sealing member of an electronic component or a glass member for buildings, such as a multilayer glass.

The laser light 10 is not particularly limited, and it may be a laser light emitted from a semiconductor laser, a carbonoxide gas laser, an excimer laser, a YAG laser, a HeNe laser, etc. The power of the laser light 10 is appropriately set according to e.g. the thickness of the sealing material layer 9, and it is, for example, preferably within the range of from 2 to 150 W. If the laser power is less than 2 W, the sealing material layer 9 may not be melted, and if it exceeds 150 W, cracking or breakage tends to be formed in the glass substrates 2 and 3. The power of the laser light 10 is more preferably within the range of from 5 to 100 W.

By the electronic device 1 of this embodiment and its production process, even when the thickness T of the sealing material layer 9 is reduced to be less than 7 μm to narrow the substrate distance, it is possible to reduce the residual stress of the glass substrates 2 and 3 at the time of laser sealing, whereby it is possible to suppress e.g. cracking or breakage in the glass substrates 2 and 3 or the sealing layer 8. Accordingly, it is possible to produce an electronic device 1 having a thin glass package with good yield, and to improve the sealing property and the hermetical sealing property of the electronic device 1 and their reliability.

By the way, in the above embodiment, explanation has been made mainly with respect to a case where the difference of the thermal expansion coefficient α₂ of both of the first glass substrate 2 and the second glass substrate 3 from the thermal expansion coefficient α₁₁ of the sealing material layer 9, is within the range of from 15 to 70(×10⁻⁷/° C.), but the construction of the glass substrates 2 and 3 is not limited thereto. When the difference of at least one thermal expansion coefficient of the thermal expansion coefficient α₂₁ of the first glass substrate 2 and the thermal expansion coefficient α₂₂ of the second glass substrate 3 from the thermal expansion coefficient α₁₁ of the sealing material layer 9 is within the range of from 15 to 70(×10⁻⁷/° C.), it is possible to obtain the effect of reducing the residual stress by an increase of fluidity by reduction of the inorganic filler amount in the sealing material and by reduction of the laser processing temperature, i.e. the effect of suppressing cracking or breakage in the glass substrates 2 and 3 or the sealing layer 8.

When the first glass substrate 2 and the second glass substrate 3 are made of the same type of glass material, of course, the difference of the thermal expansion coefficient α₂₁ of the first glass substrate 2 and the thermal expansion coefficient α₂₂ of the second glass substrate 3 from the thermal expansion coefficient α₁₁ of the sealing material layer 9, becomes within the range of from 15 to 70(×10⁻⁷/° C.). In such a case, in melt-bonding the sealing material layer 9 to the first glass substrate 2 by heat of the laser light 10 (melt-bonding of the sealing material layer 9 by laser light 10), it is possible to improve the adhesion between the first glass substrate 2 or the second glass substrate 3 and the sealing layer 8 and its reliability based on the effect to reduce the residual stress by e.g. lowering the laser processing temperature.

In a case where the first glass substrate 2 and the second glass substrate 3 are made of different types of glass materials, it is sufficient that the difference of at least one thermal expansion coefficient of the thermal expansion coefficient α₂₁ of the first glass substrate 2 and the thermal expansion coefficient α₂₂ of the second glass substrate 3 from the thermal expansion coefficient α₁₁ of the sealing material layer 9, is within the range of from 15 to 70(×10⁻⁷/° C.), and the difference of the other thermal expansion coefficient from the thermal expansion coefficient α₁₁ of the sealing material layer 9 may be less than 15×10⁻⁷/° C. Namely, in the case of using the glass substrates made of different types of glass materials, it is sufficient that the difference of the thermal expansion coefficient of a glass substrate which has a larger thermal expansion difference from the sealing material layer 9, from the thermal expansion coefficient α₁₁ of the sealing material layer 9, is within the range of from 15 to 70(×10⁻⁷/° C.).

For example, when the difference between the thermal expansion coefficient α₂₁ of the first glass substrate 2 and the thermal expansion coefficient α₁₁ of the sealing material layer 9 is within the range of from 15 to 70(×10⁻⁷/° C.), and the difference between the thermal expansion coefficient α₂₂ of the second glass substrate 3 on which the sealing material layer 9 is formed and the thermal expansion coefficient α₁₁ of the sealing material layer 9 is less than 15×10⁻⁷/° C., in the melt-bonding of the sealing material layer 9 by laser light 10, the bonding property between the first glass substrate 2 and the sealing layer 8 and its reliability are improved based on the effect to reduce the residual stress by e.g. lowering the laser processing temperature. The bonding property between the second glass substrate 2 and the sealing layer 8 and its reliability are further improved not only by the effect to reduce the residual stress by lowering the laser processing temperature, but also by a small thermal expansion difference between the second glass substrate 3 and the glass material for sealing. The same effect is obtained also in a case where the thermal expansion coefficient α₂₁ of the first glass substrate 2 and the thermal expansion coefficient α₂₂ of the second glass substrate 3 are opposite.

In other words, in the case of using a first glass substrate 2 and a second glass substrate 3 made of different types of glass materials, it is possible to set the thermal expansion coefficient α₁₁ of the sealing material layer 9 so that the difference from the thermal expansion coefficient of one of the glass substrates becomes small. Although the difference between the thermal expansion coefficient of the other glass substrate and the thermal expansion coefficient α₁₁ of the sealing material layer 9 becomes large, it is possible to suppress e.g. cracking or breakage of the glass substrates 2 and 3 or the sealing layer 8 by reducing the filler amount to maintain the fluidity of the glass material for sealing and thereby to lower the laser processing temperature. It is difficult to adjust the thermal expansion coefficient α₁₁ of the sealing material layer 9 to both of the thermal expansion coefficients of the glass substrates 2 and 3 made of different types of materials. However, in this method, it is sufficient that the thermal expansion coefficient α₁₁ is adjusted only to the thermal expansion coefficient of one of the glass substrates. Accordingly, it is possible to efficiently hermetically seal a space between the glass substrates 2 and 3 made of different types of materials.

### EXAMPLES

Now, the present invention will be described in detail with reference to specific Examples and the evaluation results. However, it should be understood that the present invention is by no means restricted to the following specific Examples, and modification within the scope of the present invention is possible.

### Example 1

First, a bismuth type glass frit (softening point: 410° C.) having a composition of 83 mass % of Bi₂O₃, 5 mass % of B₂O₃, 11 mass % of ZnO and 1 mass % of Al₂O₃ and having an average particle size of 1.0 μm; a cordierite powder as a low-expansion filler; and a laser absorbent powder having a composition of Fe₂O₃—Al₂O₃—MnO—CuO; were prepared. The average particle size was measured by a laser diffraction particle size distribution measuring apparatus (tradename: SALD2100) manufactured by Shimadzu Corporation using a laser diffraction/scattering method.

The cordierite powder as a low-expansion filler had an average particle size D₅₀ of 0.9 μm, a specific surface area of 12.4 m²/g and a specific gravity of 2.7. Further, the laser absorbent powder had an average particle size (D₅₀) of 0.8 μm, a specific surface area of 8.3 m²/g and a specific gravity of 4.8. The specific surface areas of the cordierite powder and the laser absorbent powder were measured by using an BET specific surface area measurement apparatus (Macsorb HM model-1201, manufactured by Mountech Co., Ltd.). The measurement conditions were such that the adsorbent is nitrogen, the carrier gas is helium, the measurement method is floating method (BET one point type), the evacuation temperature was 200° C., the evacuation time was 20 minutes, the evacuation pressure was N₂ gas flow/atmospheric pressure, and the sample weight was 1 g. These conditions are common to other Examples.

67.0 vol % of the above bismuth type glass frit, 19.1 vol % of the cordierite powder and 13.9 vol % of the laser absorbent powder were mixed to prepare a glass material for sealing. The total content of the cordierite powder and the laser absorbent powder was 33.0 vol %. Further, the total surface area of the cordierite powder and the laser absorbent powder in the glass material for sealing is 11.9 m²/cm³. Such a glass material for sealing and a vehicle were mixed so that the glass material for sealing would be 80 mass %, and the vehicle would be 20 mass %, to obtain a sealing material paste. The vehicle is a material prepared by dissolving ethyl cellulose (2.5 mass %) being a binder component in a solvent (97.5 mass %) comprising terpineol.

Next, a second glass substrate made of alkali-free glass (thermal expansion coefficient α₂ (50 to 250° C.): 38×10⁻⁷/° C., dimension: 90×90×0.7 mmt) was prepared, a sealing region along the entire periphery of this glass substrate was coated with the sealing material paste by a screen printing method to form a coating layer, and then dried at 120° C. for 10 minutes. Subsequently, the coating layer was fired at 480° C. for 10 minutes to form a sealing material layer having a thickness T of 3.6 μm.

The thermal expansion coefficient α₁₁ of the sealing material layer made of a material obtained by firing the sealing material paste is 80×10⁷/° C., and the difference from the thermal expansion coefficient α₂ (38×10⁻⁷/° C.) of the second glass substrate is 42×10⁻⁷/° C.

Here, the thermal expansion coefficient α₁₁ of the sealing material layer is an average linear expansion coefficient within a temperature range of from 50 to 250° C. obtained by firing the above sealing material paste within a temperature range of from 10° C. below the transition point of the sealing glass to 50° C. below the transition point (300° C. in Example 1) for 2 hours to remove the solvent and the binder component, and sintering it within a temperature range of from 30° C. above the softening point of the sealing glass to 30° C. below its crystallization point (480° C. in Example 1) for 10 minutes to obtain a sintered product, grinding the sintered product to prepare a cylindrical rod having a length of 20 mm and a diameter of 5 mm, and measuring the value by a thermomechanical analyzer (device name: TMA8310 manufactured by Rigaku Corporation). In this specification, the transition point is a temperature of the first inflexion point of differential thermal analysis (DTA), the softening point is a temperature of the fourth inflexion point of differential thermal analysis (DTA) and the crystallization point is a temperature at which the heat generation caused by crystallization in thermal differential analysis (DTA) is maximized.

The second glass substrate having the sealing material layer and the first glass substrate (a substrate comprising alkali-free glass having the same composition and the same shape as those of second glass substrate) having an element region (region in which an OEL element is formed) were laminated. Then, the sealing material layer was irradiated with laser light (semiconductor laser) having a wavelength of 940 nm, a power of 33 W and a spot diameter of 1.6 mm with a scanning speed of 10 mm/s through the second glass substrate, to melt and quickly solidify the sealing material layer to thereby seal the first glass substrate and the second glass substrate together. The heating temperature of the sealing material layer at the time of laser irradiation (measured by radiation thermometer) was 740° C. Thus, an electronic device wherein an element region was sealed by a glass package (i.e. a glass package wherein the element region is sealed by the two glass substrates) was subjected to property evaluation to be described later.

### Examples 2 to 5

An inorganic filler having a particle-form as identified in Table 1 (in Example 2, an inorganic filler containing a laser absorbent and a low-expansion filler, and in Examples 3 to 5, an inorganic filler composed solely of a laser absorbent), was mixed with a bismuth type glass frit having the same composition as in Example 1, in the ratio as shown in FIG. 1 to prepare a glass material for sealing, which was then mixed with a vehicle in the same manner as in Example 1 to prepare a sealing material paste. By using such a sealing material paste, a sealing material layer was formed at a sealing region of the second glass substrate in the same manner as in Example 1. The surface area of the inorganic filler in the glass material for sealing, the thermal expansion coefficient α₁₁ of the sealing material layer, the difference from the thermal expansion coefficient α₂ of the glass substrate, and the thickness of the sealing material layer, are as shown in Table 1.

Next, the second glass substrate having the sealing material layer and a first glass substrate having an element region (region in which an OEL element is formed) were laminated. The first and the second glass substrates are ones made of alkali-free glass in the same manner as Example 1. Then, the sealing material layer was irradiated with laser light (semiconductor laser) having a wavelength of 940 nm and a spot size of 1.6 mm with a scanning speed of 10 mm/s through the second glass substrate, to melt and quickly solidify the sealing material layer, thereby to seal the first glass substrate and the second glass substrate together. The power of laser light was set to be the value shown in Table 1. The laser processing temperature was as shown in Table 1. Thus, an electronic device wherein an element region was sealed by a glass package was subjected to property evaluation to be described later.

### Comparative Examples 1 to 5

An inorganic filler having a particle-form as identified in Table 2 (a laser absorbent and a low-expansion filler, or a laser absorbent only), was mixed with a bismuth type glass frit having the same composition as in Example 1, in the ratio as shown in Table 2 to prepare a glass material for sealing, which was then mixed with a vehicle in the same manner as in Example 1 to prepare a sealing material paste. By using such a sealing material paste, a sealing material layer was formed at a sealing region of the second glass substrate in the same manner as in Example 1. In Comparative Examples 1 and 3 to 5, a second glass substrate made of the same alkali free glass as in Example 1, was used. In Comparative Example 2, a second glass substrate made of quartz glass having a thermal expansion coefficient α₂ (50 to 250° C.) of 5×10⁻⁷/° C., was used. The surface area of the inorganic filler in the glass material for sealing, the thermal expansion coefficient α₁₁ of the sealing material layer, the difference from the thermal expansion coefficient α₂ of the glass substrate, and the thickness of the sealing material layer, are as shown in Table 1.

Next, the second glass substrate having the sealing material layer and a first glass substrate having an element region (region in which an OEL element is formed) were laminated. The first glass substrate in each case is one having the same composition and shape as the second glass substrate. Then, the sealing material layer was irradiated with laser light (semiconductor laser) having a wavelength of 940 nm and a spot size of 1.6 mm with a scanning speed of 10 mm/s through the second glass substrate, to melt and quickly solidify the sealing material layer, thereby to seal the first glass substrate and the second glass substrate together. The power of laser light was set to be the value shown in Table 2. The laser processing temperature was as shown in Table 2. Thus, an electronic device wherein an element region was sealed by a glass package was subjected to property evaluation to be described later.

Next, with respect to the external appearance of the glass package in each of Examples 1 to 5 and Comparative Examples 1 to 5, pealing of the sealing layer and cracking of the glass substrates or the sealing layer at the end of irradiation with laser light, were evaluated. The external appearance was evaluated by observation by means of an optical microscope. The airtightness of each glass package was evaluated by applying a helium-leakage test. Further, the thickness of the sealing layer was measured by cutting a glass package in each Example sealed with the sealing layer, by a dicing machine, and observing the cross section by a scanning electron microscope. These measurement/evaluation results are shown in Tables 1 and 2 together with the production conditions for glass packages.

TABLE 1

| | | | Ex. 1 | Ex. 2 | Ex. 3 | Ex. 4 | Ex. 5 |
|---|---|---|---|---|---|---|---|
| Glass | Sealing glass | Material | Bismuth glass | | | | |
| material for | | Content (vol %) | 67.0 | 74.3 | 69.7 | 62.9 | 75.1 |
| sealing | Laser absorbent | Material | Fe—Al—Mn—Cu—O | | | | |
| | | Average particle shape D50 (μm) | 0.8 | 0.8 | 0.8 | 0.8 | 0.8 |
| | | Specific surface area (m²/g) | 8.3 | 8.3 | 8.3 | 6.1 | 8.3 |
| | | Specific gravity (g/cm³) | 4.8 | 4.8 | 4.8 | 4.8 | 4.8 |
| | | Content (vol %) | 13.9 | 14.7 | 30.3 | 37.1 | 24.9 |
| | Low-expansion | Material | Cordierite | | — | — | — |
| | filler | Average particle shape D50 (μm) | 0.9 | 0.9 | — | — | — |
| | | Specific surface area (m²/g) | 12.4 | 12.4 | — | — | — |
| | | Specific gravity (g/cm³) | 2.7 | 2.7 | — | — | — |
| | | Content (vol %) | 19.1 | 11.0 | — | — | — |
| | Content of inorganic filler (vol %) | | 33.0 | 25.7 | 30.3 | 37.1 | 24.9 |
| | Surface area of inorganic filler in glass material for sealing | | 11.9 | 9.5 | 12.1 | 10.9 | 9.9 |
| | (m²/cm³) | | | | | | |
| | Thermal expansion coefficient α₁₁ (×10⁻⁷/° C.) | | 80 | 90 | 105 | 104 | 105 |
| Glass substrate | | | Alkali-free glass (α₂ = 38 × 10⁻⁷/° C.) | | | | |
| Thickness of sealing material layer (μm) | | | 3.6 | 5.5 | 3.4 | 3.4 | 3.4 |
| α-Difference between glass substrate and sealing material layer | | | 42 | 52 | 67 | 66 | 67 |
| (×10⁻⁷/° C.) | | | | | | | |
| Sealing | Laser power (W) | | 33 | 33 | 36 | 35 | 35 |
| step | Laser scanning speed (mm/s) | | 10 | 10 | 10 | 10 | 10 |
| | Processing temperature (° C.) | | 740 | 740 | 790 | 770 | 770 |
| | Thickness of sealing layer (μm) | | 3.5 | 5.4 | 3.1 | 3.2 | 3.2 |
| Evaluation | External | Pealing | None | None | None | None | None |
| result | appearance | Cracking | None | None | None | None | None |

| | | | | | |
|---|---|---|---|---|---|
| Airtightness | Exist | Exist | Exist | Exist | Exist |

TABLE 2

| | | | Comp. | Comp. | Comp. | Comp. | Comp. |
|---|---|---|---|---|---|---|---|
| | | | Ex. 1 | Ex. 2 | Ex. 3 | Ex. 4 | Ex. 5 |
| Glass | Sealing glass | Material | Bismuth glass | | | | |
| material for | | Content (vol %) | 49.8 | 74.3 | 50.7 | 45.6 | 40.7 |
| sealing | Laser absorbent | Material | Fe—Al—Mn—Cu—O | | | | |
| | | Average particle shape D50 (μm) | 0.8 | 0.8 | 0.8 | 0.8 | 0.8 |
| | | Specific surface area (m²/g) | 8.3 | 8.3 | 8.3 | 8.3 | 8.3 |
| | | Specific gravity (g/cm³) | 4.8 | 4.8 | 4.8 | 4.8 | 4.8 |
| | | Content (vol %) | 4.4 | 14.7 | 49.3 | 54.4 | 59.3 |
| | Low-expansion | Material | Cordierite | | — | — | — |
| | filler | Average particle shape D50 (μm) | 0.9 | 0.9 | — | — | — |
| | | Specific surface area (m²/g) | 12.4 | 12.4 | — | — | — |
| | | Specific gravity (g/cm³) | 2.7 | 2.7 | — | — | — |
| | | Content (vol %) | 45.8 | 11.0 | — | — | — |
| | Content of inorganic filler (vol %) | | 50.2 | 25.7 | 49.3 | 54.4 | 59.3 |
| | Surface area of inorganic filler in glass material for sealing | | 4.6 | 9.5 | 19.6 | 21.7 | 23.6 |
| | (m²/cm³) | | | | | | |
| | Thermal expansion coefficient α₁₁ (×10⁻⁷/° C.) | | 52 | 80 | 104 | 103 | 103 |
| Glass substrate | | | Alkali-free | Quartz | Alkali-free glass *1 | | |
| | | | glass *1 | glass *2 | | | |
| Thickness of sealing material layer (μm) | | | 3.6 | 3.6 | 3.6 | 3.6 | 3.6 |
| α-Difference between glass substrate and sealing material layer | | | 14 | 75 | 66 | 65 | 65 |
| (×10⁻⁷/° C.) | | | | | | | |
| Sealing | Laser power (W) | | 45 | 32 | 37 | 37 | 37 |
| step | Laser scanning speed (mm/s) | | 10 | 10 | 10 | 10 | 10 |
| | Processing temperature (° C.) | | 940 | 720 | 800 | 800 | 800 |
| | Thickness of sealing layer (μm) | | 3.4 | 3.4 | 3.6 | 3.4 | 3.8 |
| Evaluation | External | Pealing | None | None | Exist | Exist | None |
| result | appearance | Cracking | Exist | Exist | Exist | Exist | Exist |
| | Airtightness | | None | None | None | None | None |

*1: Alkali-free glass (α₂ = 38 × 10⁻⁷/° C.)
*2: Quartz glass (α₂ = 5 × 10⁻⁷/° C.)

As evident from Tables 1 and 2, each of glass packages in Examples 1 to 5 is excellent in external appearance and airtightness. On the other hand, in Comparative Example 1 wherein the content of the low-expansion filler was increased, and the laser processing temperature was made to be correspondingly high, the residual stress formed in the glass substrates in the laser-sealing step was large, whereby cracking was observed in the glass substrates or the sealing layer. Further, in a case where the difference in thermal expansion was too large between the sealing layer and the glass substrate (Comparative Example 2), cracking was observed in the glass substrate or the sealing layer, even if the amount of the inorganic filler was reduced. Further, in a case where the amount of the inorganic filler was large, and the difference in thermal expansion between the sealing layer and the glass substrate was large (Comparative Examples 3 to 5), cracking was confirmed in the glass substrate or the sealing layer.

### Example 6

In this Example, a bismuth type glass frit (softening point: 430° C.) having a composition comprising 79.3 mass % of Bi₂O₃, 7.1 mass % of B₂ O₃, 7.6 mass % of ZnO, 5.6 mass % of BaO and 0.4 mass % of Al₂O₃ was used by replacing a part of ZnO as a glass component of sealing glass with BaO. Other conditions were the same as in Example 1, and an electronic device wherein an element region was sealed by a glass package, was subjected to the above-described property evaluation. As a result, it was confirmed that no peeling or cracking was observed as the external appearance, and the airtightness was also excellent. Further, with this glass frit, by the above replacement, the crystallization potential is lowered, the fluidity of glass is improved at the time of laser sealing, and the laser processing temperature can be lowered, whereby the effect to reduce the residual stress can also be expected.

### Example 7

In this Example, a bismuth type glass frit (softening point: 430° C.) having a composition comprising 81.8 mass % of Bi₂ O₃, 6.0 mass % of B₂ O₃, 10.6 mass % of ZnO, 0.7 mass % of SiO₂ and 0.9 mass % of Al₂O₃ was used by adding very small amounts of Al₂O₃ and SiO₂ to the glass components for sealing glass. Other conditions were the same as in Example 1, and an electronic device wherein an element region was sealed by a glass package, was subjected to the above-described property evaluation. As a result, it was confirmed that no peeling or cracking was observed as the external appearance, and the airtightness was also excellent. Further, with this glass frit, by adding very small amounts of Al₂O₃ and SiO₂, the crystallization potential is lowered, the fluidity of glass is improved at the time of laser sealing, and the laser processing temperature can be lowered, whereby the effect to reduce the residual stress can also be expected.

### Example 8

In this Example, an electronic device wherein an element region was sealed by a glass package in the same manner as in Example 7, was subjected to the above-described property evaluation, except that the laser absorbent was changed to one having a Fe₂ O₃—Al₂ O₃—MnO—Co₂ O₃—SiO₂ composition. As a result, it was confirmed that no peeling or cracking was observed as the external appearance, and the airtightness was also excellent.

In this specification, the construction of the electronic device of the present invention and the process for producing the electronic device have been described by using an expression of “the first glass substrate” and “the second glass substrate”. In these descriptions, the first glass substrate may be substituted by the second glass substrate, or the second glass substrate may be substituted by the first glass substrate, within the concept of the present invention. In the above Examples, a case where one sealing region is provided on a glass substrate, is described, but the present invention is applicable to a case where a plurality of sealing regions are formed on a glass substrate. For example, there may be a case where a total of nine sealing regions are disposed in 3 rows and 3 columns on a glass substrate. In such a case, nine electronic devices may be formed on one glass substrate.

### INDUSTRIAL APPLICABILITY

According to the present invention, at the time of narrowing the distance between two glass substrates in an electronic device packaged by the two glass substrates, it is possible to prevent cracking or breakage of the glass substrates or the sealing layer, which is likely to occur at the time of laser sealing. Accordingly, it is possible to improve the sealing property between the glass substrates or its reliability, whereby it becomes possible to present an electronic device having the airtightness or its reliability improved, with good reproducibility, and the present invention is useful for an electronic device having a structure wherein the distance between the two glass substrates is narrow.

This application is a continuation of PCT Application No. PCT/JP2011/080092, filed Dec. 26, 2011, which is based upon and claims the benefit of priority from Japanese Patent Application No. 2010-291040 filed on Dec. 27, 2010. The contents of those applications are incorporated herein by reference in its entirety.

### REFERENCE SYMBOLS

1: Electronic device, 2: first glass substrate, 2a: first surface, 3: second glass substrate, 3a: second surface, 4: electronic element portion, 5: element region, 6: first sealing region, 7: second sealing region, 8: sealing layer, 9: sealing material layer, 10: laser light.

What is claimed is:

1. A glass member provided with a sealing material layer, which comprises a glass substrate having a surface having a sealing region; and, formed on the sealing region of the glass substrate, a sealing material layer having a thickness of less than 7 μm and made of a material obtained by firing a glass material for sealing that contains a sealing glass and an inorganic filler containing a laser absorbent;
wherein the glass material for sealing contains the inorganic filler in an amount within a range of from 2 to 44 vol % based on the total amount of the sealing glass and the inorganic filler, and the surface area of the inorganic filler in the glass material for sealing is within a range of more than 6 m²/cm³ and less than 14 m²/cm³; and
wherein the difference between the thermal expansion coefficient α₁₁ of the material of the sealing material layer and the thermal expansion coefficient α₂ of the glass substrate is within a range of from 15 to 70(×10⁻⁷/° C.).

2. The glass member provided with a sealing material layer according to claim 1, wherein the glass material for sealing contains the laser absorbent in an amount within the range of from 2 to 40 vol % based on the total amount of the sealing glass and the inorganic filler.

3. The glass member provided with a sealing material layer according to claim 1, wherein the inorganic filler further contains a low-expansion filler, and the glass material for sealing contains the low-expansion filler in an amount within a range of from 0.1 to 40 vol % based on the total amount of the sealing glass and the inorganic filler.

4. The glass member provided with a sealing material layer according to claim 1, wherein the laser absorbent comprises at least one metal selected from Fe, Cr, Mn, Co, Ni and Cu or at least one compound containing the metal.

5. The glass member provided with a sealing material layer according to claim 1, wherein the low-expansion filler comprises at least one member selected from silica, alumina, zirconia, zirconium silicate, aluminum titanate, mullite, cordierite, eucryptite, spodumene, a zirconium phosphate compound, quartz solid solution, soda lime glass and borosilicate glass.

6. The glass member provided with a sealing material layer according to claim 1, wherein the glass substrate comprises alkali-free glass or soda lime glass, and the sealing glass comprises bismuth glass or tin-phosphate glass.

7. An electronic device which comprises a first glass substrate having a first surface having a first sealing region;
a second glass substrate having a second surface having a second sealing region corresponding to the first sealing region and disposed so that the second surface is opposed to the first surface;
an electronic element portion provided between the first glass substrate and the second glass substrate; and
a sealing layer which is formed between the first sealing region of the first glass substrate and the second sealing region of the second glass substrate to seal the electronic element portion and which has a thickness of less than 7 μm and is made of a material obtained by melting and solidifying a glass material for sealing that contains a sealing glass and an inorganic filler containing a laser absorbent;
wherein the glass material for sealing contains the inorganic filler in an amount within a range of from 2 to 44 vol % based on the total amount of the sealing glass and the inorganic filler, and the surface area of the inorganic filler in the glass material for sealing is within a range of more than 6 m²/cm³ and less than 14 m²/cm³; and
wherein the difference between the thermal expansion coefficient α₁₂ of the material of the sealing layer and the thermal expansion coefficient α₂ of at least one of the first glass substrate and the second glass substrate is within the range of from 15 to 70(×10⁻⁷/° C.).

8. The electronic device according to claim 7, wherein the glass material for sealing contains the laser absorbent in an amount within the range of from 2 to 40 vol % based on the total amount of the sealing glass and the inorganic filler.

9. The electronic device according to claim 7, wherein the inorganic filler further contains a low-expansion filler, and the glass material for sealing contains the low-expansion filler in an amount within a range of from 0.1 to 40 vol % based on the total amount of the sealing glass and the inorganic filler.

10. A process for producing an electronic device, which comprises preparing a first glass substrate having a first surface having a first sealing region;
preparing a second glass substrate having a second surface having a second sealing region corresponding to the first sealing region and provided with a sealing material layer having a thickness of less than 7 μm formed on the second sealing region and made of a material obtained by firing a glass material for sealing that contains a sealing glass and an inorganic filler containing a laser absorbent;
laminating the first glass substrate and the second glass substrate with the sealing material layer interposed so that the first surface and the second surface are opposed to each other; and
irradiating the sealing material layer with a laser light through the first glass substrate or the second glass substrate to melt and solidify the sealing material layer thereby to form a sealing layer to seal the electronic element portion provided between the first glass substrate and the second glass substrate;
wherein the glass material for sealing contains the inorganic filler in an amount within a range of from 2 to 44 vol % based on the total amount of the sealing glass and the inorganic filler, and the surface area of the inorganic filler in the glass material for sealing is within a range of more than 6 m²/cm³ and less than 14 m²/cm³; and
wherein the difference between the thermal expansion coefficient α₁₁ of the material of the sealing material layer and the thermal expansion coefficient α₂ of at least one of the first glass substrate and the second glass substrate is within a range of from 15 to 70(×10⁻⁷/° C.).

11. The process for producing an electronic device according to claim 10, wherein the glass material for sealing contains the laser absorbent in an amount within the range of from 2 to 40 vol % based on the total amount of the sealing glass and the inorganic filler.

12. The process for producing an electronic device according to claim 10, wherein the inorganic filler further contains a low-expansion filler, and the glass material for sealing contains the low-expansion filler in an amount within a range of from 0.1 to 40 vol % based on the total amount of the sealing glass and the inorganic filler.
